(19) United States
(12) Patent Application Publication
(10) Pub. No.: US 2025/0081573 A1
(43) Pub. Date: Mar. 6, 2025

(54) MIDDLE VOLTAGE TRANSISTOR AND FABRICATING METHOD OF THE SAME

(71) Applicant: UNITED MICROELECTRONICS CORP., Hsin-Chu City (TW)

(72) Inventor: Shin-Hung Li, Nantou County (TW)

(73) Assignee: UNITED MICROELECTRONICS CORP., Hsin-Chu City (TW)

(21) Appl. No.: 18/369,815

(22) Filed: Sep. 18, 2023

(30) Foreign Application Priority Data
Aug. 28, 2023 (CN) 202311083980.1

(51) Int. Cl. H01L 29/66; H01L 29/78

(52) U.S. Cl. CPC H10D 64/021; H10D 30/0227; H10D 30/601

(57) ABSTRACT

A middle voltage transistor structure includes a substrate. A gate structure is disposed on the substrate. A source lightly doped region and a drain lightly doped region are disposed within the substrate at two sides of the gate structure. A conductive structure contacts the lightly drain doped region. A first spacer surrounds the gate structure and a second spacer surrounds the conductive structure. The first spacer contacts the second spacer.

### BACKGROUND OF THE INVENTION

### 1. Field of the Invention

The present invention relates to a middle voltage transistor structure, in particular to a middle voltage transistor structure and a manufacturing method thereof which utilizes a conductive structure disposed on a substrate to reduce a pitch of the middle voltage transistor structure.

### 2. Description of the Prior Art

Compared with liquid crystal display (LCD) panels, organic light emitting diode (OLED) panels has the advantages of simple manufacturing process, wide viewing angle, low cost, thin thickness, wide operating temperature range, and self-luminescence. Therefore, OLED can be used as pixels in the display panel, and can replace the LCD panel.

Because the users require better image quality and OLED display device design and process technology are mature, the pixels on the OLED panel are increased day by day. Therefore, pitches between OLED pixels need to be reduced to get high quality OLED panels.

### SUMMARY OF THE INVENTION

In view of this, the present invention provides a middle voltage transistor structure with a decreased pitch, which is especially suitable as a switch element of an active matrix organic light emitting diode (AMOLED).

According to a preferred embodiment of the present invention, a middle voltage transistor structure includes a gate structure disposed on the substrate. A source lightly doped region and a drain lightly doped region are embedded within the substrate at two sides of the gate structure. A conductive structure contacts the lightly drain doped region. A first spacer surrounds the gate structure. A second spacer surrounds the conductive structure; wherein the first spacer contacts the second spacer.

According to another preferred embodiment of the present invention, a layout of a middle voltage transistor structure includes a substrate, wherein the substrate includes an active region and a shallow trench isolation surrounding the active region, and the active region includes four corners. A gate structure is disposed on the substrate, the gate structure extends along a first direction, and the gate structure intersects the active region and covers the shallow trench isolation. A conductive structure is disposed on a side of the gate structure, and the conductive structure extends along the first direction. The conductive structure covers the shallow trench isolation and covers one of the four corners.

According to yet another preferred embodiment of the present invention, a fabricating method of a middle voltage transistor structure includes providing a substrate. Next, a source lightly doped region and a drain lightly doped region are formed to be embedded in the substrate. Then, a middle voltage dielectric layer is formed to be disposed between the source lightly doped region and the drain lightly doped region. After that, a first polysilicon layer and a second polysilicon layer are simultaneously formed, wherein the first polysilicon layer overlaps the middle voltage dielectric layer, and the second polysilicon layer covers part of the drain lightly doped region. Finally, a first spacer and a second spacer are formed, wherein the first spacer surrounds the first polysilicon layer and the middle voltage dielectric layer, the second spacer surrounds the second polysilicon layer, and the first spacer contacts the second spacer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 4 depict a fabricating method of a middle voltage transistor structure according to a first preferred embodiment of the present invention, wherein:

FIG. 1 depicts a substrate with an STI, a source lightly doped region and a drain lightly doped region thereon;

FIG. 2 is a fabricating stage in continuous of FIG. 1;

FIG. 3 is a fabricating stage in continuous of FIG. 2; and

FIG. 4 is a fabricating stage in continuous of FIG. 3.

FIG. 5 to FIG. 6 depict a fabricating method of a middle voltage transistor structure according to the second preferred embodiment of the present invention, wherein:

FIG. 5 is a fabricating stage in continuous of FIG. 1; and

FIG. 6 is a fabricating stage in continuous of FIG. 5.

FIG. 7 depicts a layout of a middle voltage transistor structure according to a preferred embodiment of the present invention.

FIG. 8 depicts a layout of a middle voltage transistor structure according to another preferred embodiment of the present invention.

FIG. 9 depicts a layout of a middle voltage transistor structure according to another preferred embodiment of the present invention.

FIG. 10 depicts a layout of a middle voltage transistor structure according to another preferred embodiment of the present invention.

### DETAILED DESCRIPTION

FIG. 1 to FIG. 4 depict a fabricating method of a middle voltage transistor structure according to a first preferred embodiment of the present invention.

As shown in FIG. 1, a substrate 10 is provided. A shallow trench isolation (STI) 12 is disposed in the substrate 10. The STI 12 defines an active region A on the substrate 10. Next, a mask layer 14 is formed to cover the active region A of the substrate 10. The position of the mask layer 14 will become the position of the gate structure of the middle voltage transistor structure later. Then, an ion implantation process is performed to form a source lightly doped region 16 and a drain lightly doped region 18 embedded in the substrate 10 at two sides of the mask layer 14 by using the mask layer 14 as a mask.

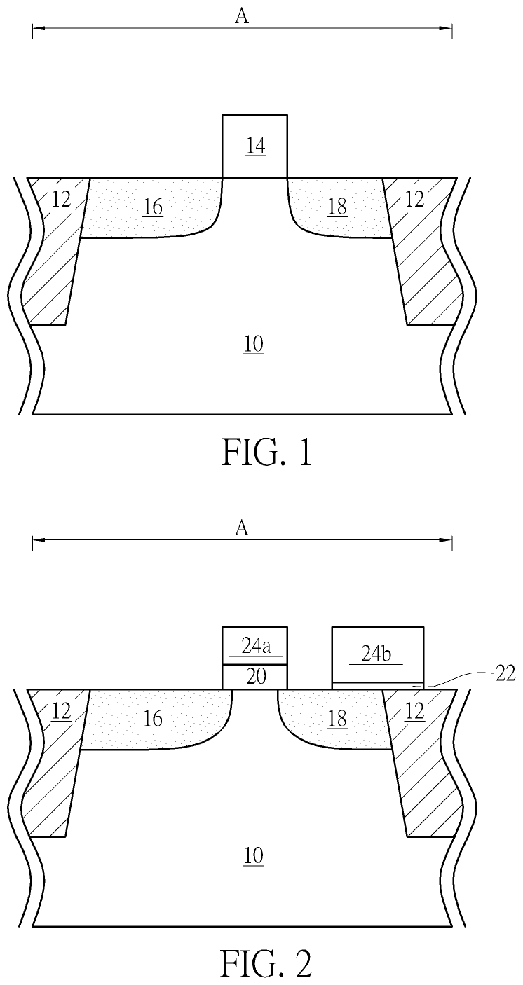

As shown in FIG. 2, the mask layer 14 is removed. After that, a middle voltage dielectric layer 20 is formed to at least cover the surface of the substrate 10 between the source lightly doped region 16 and the drain lightly doped region 18 and a low voltage dielectric layer 22 is formed to cover at least part of the drain lightly doped region 18 and part of the STI 12. The middle voltage dielectric layer 20 can be formed by using a deposition process. For example, a middle voltage material layer is formed firstly. The middle voltage material layer includes silicon oxide, silicon oxynitride or other dielectric materials. The fabricating method of the low voltage dielectric layer 22 includes an oxidation process or a deposition process. For example, a low voltage material layer is formed by a deposition process. The low voltage material layer includes silicon oxide. Then, a polysilicon layer is blanketly formed to cover the active region A of the substrate 10. Later, the polysilicon layer, the middle voltage material layer and low voltage material layer are patterned to simultaneously form a first polysilicon layer 24a and a second polysilicon layer 24b. The remaining middle voltage material layer serves as the middle voltage dielectric layer 20, and the remaining low voltage material layer serves as the low voltage dielectric layer 22. The first polysilicon layer 24a overlaps the middle voltage dielectric layer 20, and the second polysilicon layer 24b overlaps the low voltage dielectric layer 22. That is, the second polysilicon layer 24b covers part of the drain lightly doped region 18.

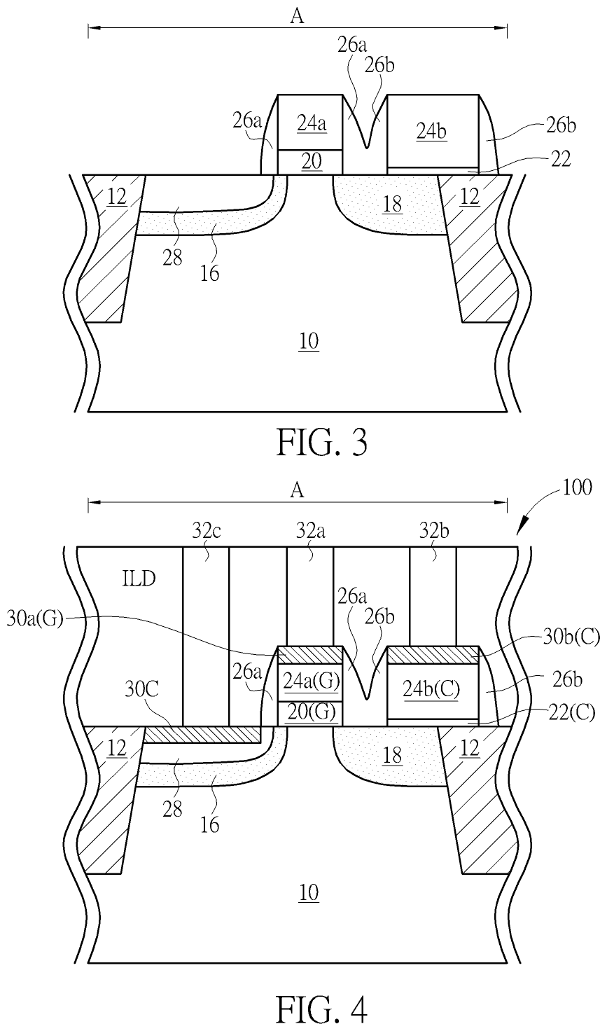

As shown in FIG. 3, a spacer material layer (not shown) is formed to cover the substrate 10, the first polysilicon layer 24a and the second polysilicon layer 24b. Next, the spacer material layer is etched to form a first spacer 26a and a second spacer 26b. The first spacer 26a surrounds the first polysilicon layer 24a and the middle voltage dielectric layer 20, and the second spacer 26b surrounds the second polysilicon layer 24b and the low voltage dielectric layer 22. It is noteworthy that the first spacer 26a directly above the drain lightly doped region 18 contacts the second spacer 26b. That is, the drain lightly doped region 18 is covered by the first polysilicon layer 24a, the second polysilicon layer 24b, the first spacer 26a and the second spacer 26b. Next, by using the first polysilicon layer 24a, the second polysilicon layer 24b, the first spacer 26a, and the second spacer 26b as a mask to perform an ion implantation process to form a source doped region 28 in the source lightly doped region 16.

As shown in FIG. 4, a silicide process is performed by using the first spacer 26a and the second spacer 26b as a mask to transform part of the first polysilicon layer 24a into a first silicide 30a, part of the second polysilicon layer 24b into a second silicide 30b and part of the source doped region 28 into a third silicide 30c. Next, an interlayer dielectric layer ILD is formed to cover the substrate 10. After that, a first conductive plug 32a, a second conductive plug 32b and a third conductive plug 32c are formed in the interlayer dielectric layer ILD. The first conductive plug 32a contacts the first silicide 30a, the second conductive plug 32b contacts the second silicide 30b, and the third conductive plug 32c contacts the third silicide 30c. Then, current is formed between the source doped region 28, the source lightly doped region 16 and the second polysilicon layer 24b at 8 to 10 volts to break down the low voltage dielectric layer 22. Now, a middle voltage transistor structure 100 of the present invention is completed. Because 8 to 10 volts exceeds the voltage that the low voltage dielectric layer 22 can withstand, the low voltage dielectric layer 22 is damage and broken down and resistance the low voltage dielectric layer 22 drops rapidly under 8 to 10 volts. Therefore, the low voltage dielectric layer 22 becomes conductive. In subsequent operation of the middle voltage transistor structure 100, current can flow between the source doped region 28, the substrate 10, the low voltage dielectric layer 22, and the second polysilicon layer 24b.

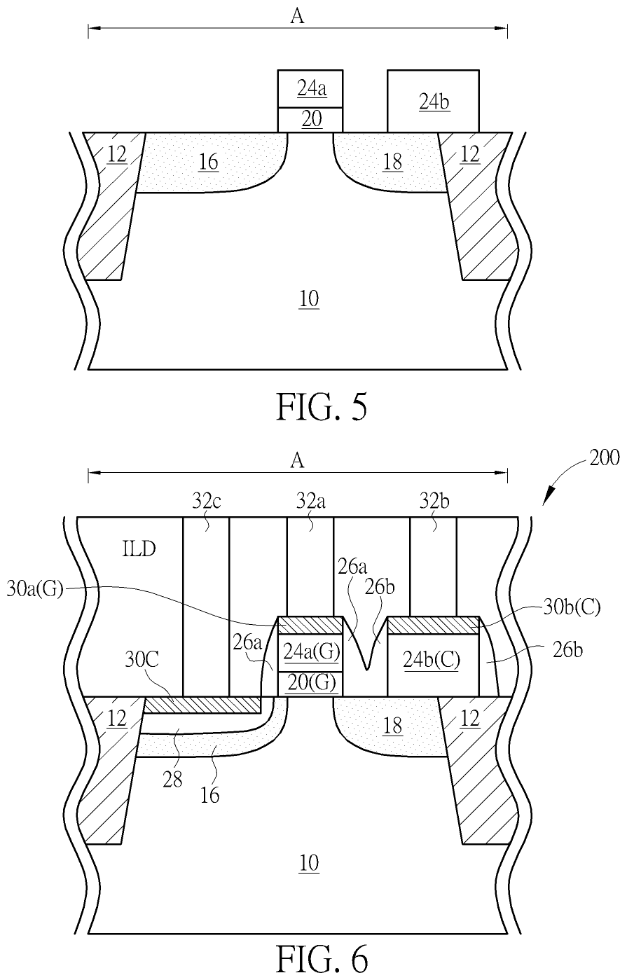

FIG. 5 to FIG. 6 depict a fabricating method of a middle voltage transistor structure according to the second preferred embodiment of the present invention, wherein elements which are substantially the same as those in the first preferred embodiment are denoted by the same reference numerals; an accompanying explanation is therefore omitted.

FIG. 5 is in continuous of the steps in FIG. 1. The difference between the second preferred embodiment and the first preferred embodiment is that the low voltage dielectric layer 22 is formed in the second FIG. 2 of the first preferred embodiment. However, in FIG. 5 of the second preferred embodiment, no low voltage dielectric layer is formed, and the second polysilicon layer 24b is formed to directly cover and contact the drain lightly doped region 18. As shown in FIG. 6, the first spacer 26a, the second spacer 26b, the source doped region 28, the first silicide 30a, the second silicide 30b, the third silicide 30c, the interlayer dielectric layer ILD, the first conductive plug 32a, the second conductive plug 32b and the third conductive plug 32c are formed in a way the same as that described in the first preferred embodiment, an accompanying explanation is therefore omitted. Now, the middle voltage transistor structure 200 is completed. Since the middle voltage transistor structure 200 has no low voltage dielectric layer, the process to break down the low voltage dielectric layer is not needed.

According to a preferred embodiment of the present invention, as shown in FIG. 4, a middle voltage transistor structure 100 includes a substrate 10. The substrate 10 includes a silicon substrate, a germanium substrate, a gallium arsenide substrate, a silicon germanium substrate, an indium phosphide substrate, a gallium nitride substrate, a silicon carbide substrate or a silicon-on-insulator (SOI) substrate. An STI 12 is disposed on the substrate 10, and the STI 12 includes silicon oxide. The STI 12 defines an active region A on the substrate 10. A gate structure G is disposed on the active region A of the substrate 10. A source lightly doped region 16 and a drain lightly doped region 18 are embedded in the substrate 10 at two sides of the gate structure G. A source doped region 28 is disposed in the source lightly doped region 16, wherein no drain doped region is disposed in the drain lightly doped region 18. A conductive structure C contacts the drain lightly doped region 18 and the STI 12. A first spacer 26a surrounds the gate structure G, and a second spacer 26b surrounds the conductive structure C. The second spacer 26b contacts the drain lightly doped region 18, wherein the first spacer 26a and the second spacer 26b directly above the drain lightly doped region 18 are merged together. The first spacer 26a and the second spacer 26b are preferably made of insulating materials such as silicon nitride, silicon oxide, silicon oxynitride or the like. The drain lightly doped region 18, the source lightly doped region 16 and the source doped region 28 may include N-type or P-type dopants. The dopant concentration of the source lightly doped region 16 is the same as the dopant concentration of the drain lightly doped region 18. The dopant concentration of the source doped region 28 is greater than the dopant concentration of the source lightly doped region 16.

The top surface of the gate structure G is aligned with the top surface of the conductive structure C. The gate structure G includes a middle voltage dielectric layer 20, a first polysilicon layer 24a and a first silicide 30a disposed from bottom to top. The conductive structure C includes a low voltage dielectric layer 22, a second polysilicon layer 24b and a second silicide 30b disposed on the substrate 10 from bottom to top. A thickness of the middle voltage dielectric layer 20 is greater than a thickness of the low voltage dielectric layer 22. When the middle voltage transistor structure 100 is turned on, current flows between the source doped region 28, the substrate 10, the drain lightly doped region 18, the low voltage dielectric layer 22 and the conductive structure C. According to another preferred embodiment of the present invention, as shown in FIG. 6, the difference between the middle voltage transistor structure 200 and the middle voltage transistor structure 100 is that there is no low voltage dielectric layer in the conductive structure C of the middle voltage transistor structure 200. Therefore, the second polysilicon layer 24b of the middle voltage transistor structure 200 is in direct contact with the drain lightly doped region 18, and other elements are the same as those of the middle voltage transistor structure 100, and the description is omitted.

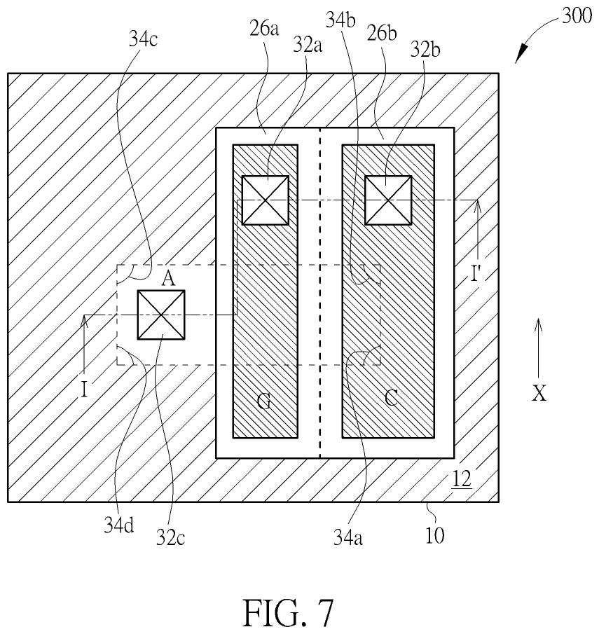

FIG. 7 depicts a layout of a middle voltage transistor structure according to a preferred embodiment of the present invention, wherein FIG. 4 and FIG. 6 are sectional views taken along line I-I′ in FIG. 7. In FIG. 7, for the sake of clarity and simplicity, the first silicide, the second silicide, the third silicide, the source lightly doped region, the source doped region, the drain lightly doped region and interlayer dielectric layer are omitted. Elements which are substantially the same as those in the first preferred embodiment are denoted by the same reference numerals; an accompanying explanation is therefore omitted.

As shown in FIG. 7, a layout 300 of a middle voltage transistor structure includes a substrate 10. The substrate 10 includes an active region A and an STI 12 surrounding the active region A. The outline of the active region A includes four corners 34a/34b/34c/34d. A gate structure G is disposed on the substrate 10, and the gate structure G extends along a first direction X. The gate structure G and the active region A are intersected with each other and both ends of the gate structure G cover the STI 12. A conductive structure C is disposed on one side of the gate structure G, and the conductive structure C extends along the first direction X. The conductive structure C covers two corners 34a/34b of the four corners 34a/34b/34c/34d of the active region A and covers the STI 12. That is, the conductive structure C covers one end of the active region A. In addition, along the first direction X, the length of the conductive structure C is the same as the length of the gate structure G.

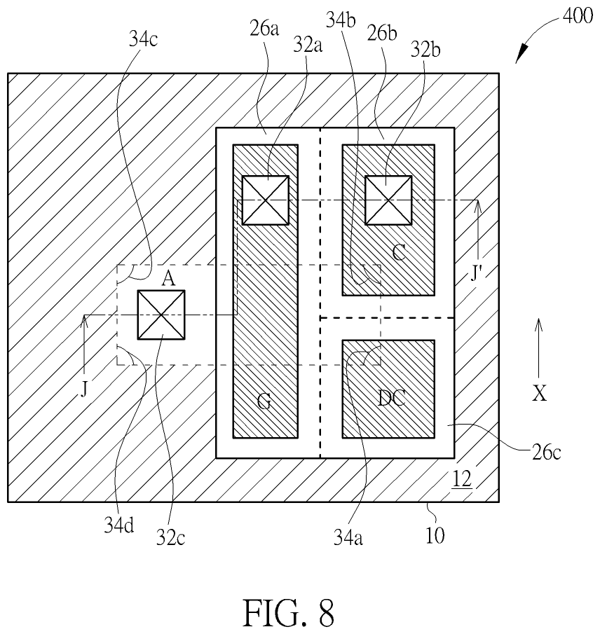

FIG. 8 depicts a layout of a middle voltage transistor structure according to another preferred embodiment of the present invention, wherein FIG. 4 and FIG. 6 are sectional views taken along line J-J′ in FIG. 8. In FIG. 8, for the sake of clarity and simplicity, the first silicide, the second silicide, the third silicide, the source lightly doped region, the source doped region, the drain lightly doped region and interlayer dielectric layer are omitted. Elements which are substantially the same as those in FIG. 7 are denoted by the same reference numerals; an accompanying explanation is therefore omitted.

The difference between FIG. 8 and FIG. 7 is that in FIG. 8, along the first direction X, the length of the conductive structure C is smaller than the length of the gate structure G. Therefore, the conductive structure C only covers the corner 34b which is one of the four corners 34a/34b/34c/34d of the active region A and covers the STI 12. FIG. 8 further includes a dummy conductive structure DC contacts the drain lightly doped region (not shown) and STI 12. The dummy conductive structure DC and the conductive structure C are disposed at the same side of the gate structure G and the dummy conductive structure DG is not connected to the conductive structure C. The dummy conductive structure DC only covers the corner 34a which is one of the four corners 34a/34b/34c/34d of the active region A and covers the STI 12. The corner 34a covered by the dummy conductive structure DC is different from the corner 34b covered by the conductive structure C. In addition, the dummy conductive structure DC and the conductive structure C are stacked in the same order by same material layers. For example, as shown in FIG. 4, the low voltage dielectric layer 22, the second polysilicon layer 24b and the second silicide 30b are stacked from bottom to top. Alternatively, as shown in FIG. 6, the second polysilicon layer 24b and the second silicide 30b are stacked from bottom to top. A third spacer 26c surrounds the dummy conductive structure DC, and the third spacer 26c contacts the second spacer 26b and the first spacer 26a.

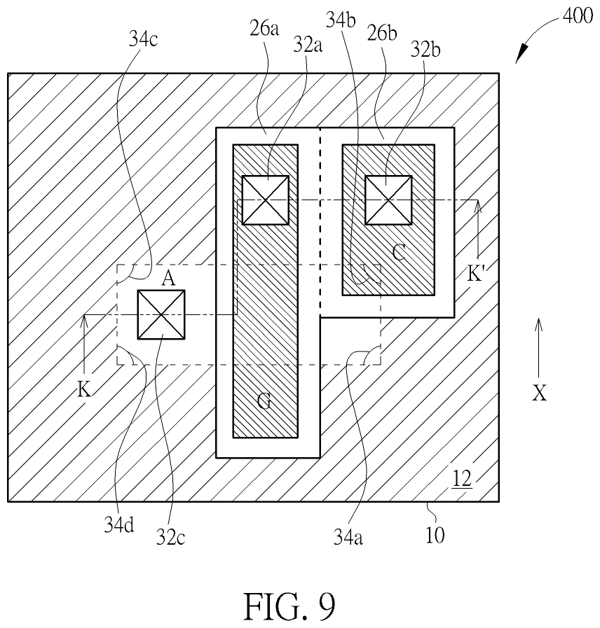

FIG. 9 depicts a layout of a middle voltage transistor structure according to another preferred embodiment of the present invention, wherein FIG. 4 and FIG. 6 are sectional views taken along line K-K′ in FIG. 9. In FIG. 9, for the sake of clarity and simplicity, the first silicide, the second silicide, the third silicide, the source lightly doped region, the source doped region, the drain lightly doped region and interlayer dielectric layer are omitted. Elements which are substantially the same as those in FIG. 7 are denoted by the same reference numerals; an accompanying explanation is therefore omitted.

The difference between FIG. 9 and FIG. 8 is that in FIG. 9, there is no dummy conductive structure, so the interlayer dielectric layer directly contacts the drain lightly doped region. Please refer to FIG. 4 or FIG. 6 for the location of the interlayer dielectric layer and the drain lightly doped region.

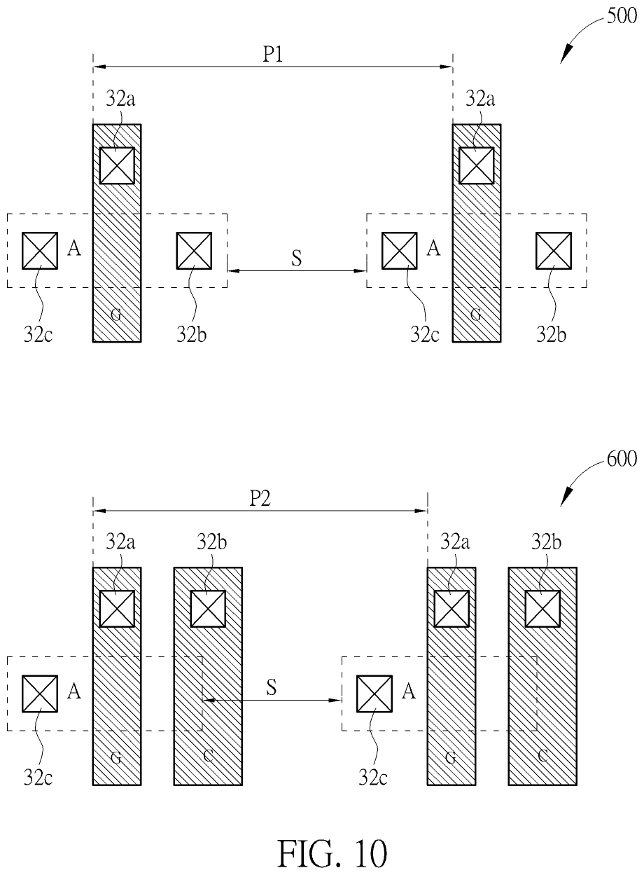

FIG. 10 depicts a layout of a middle voltage transistor structure according to another preferred embodiment of the present invention, wherein elements which are substantially the same as those in the first preferred embodiment are denoted by the same reference numerals; an accompanying explanation is therefore omitted.

As shown in FIG. 10, the upper layout 500 is composed of two middle voltage transistor structures without using conductive structures, and the lower layout 600 is composed of two middle voltage transistor structures using conductive structures. A drain doped region (not shown) is disposed in the drain lightly doped region (not shown) of the middle voltage transistor structure of the layout 500, and the upper surface of the drain doped region is the top surface of the substrate. The middle voltage transistor structure of the layout 600 uses a conductive structure C to replace part of the drain doped region. Therefore, compared with the layout 500, the active region A corresponding to the drain doped region in the layout 600 becomes smaller, therefore the pitch P2 between adjacent middle voltage transistor structures in the layout 600 becomes smaller. In addition, in the layout 500 and the layout 600, the distance S between adjacent active regions A is the same. According to a preferred embodiment of the present invention, the pitch of the middle voltage transistor structures in the layout 600 is a pitch P2, the pitch of the middle voltage transistor structures of the layout 500 is a pitch P1, and the pitch P2 is 0.85 times of the pitch P1.

The middle voltage transistor structure in the present invention is suitable for any devices that require high density. For example, the middle voltage transistor structure can be used as a semiconductor switch for pixels in an active array organic light emitting diode display. Because of the reduced pitch of the middle voltage transistor in the present invention, higher pixel density can be provided. In addition, when pitches are shrunk, using conductive structures can prevent current leakage of the middle voltage transistor structure. Furthermore, because the operating current of the organic light emitting diode is extremely small, even if current of the middle voltage transistor structure is decreased, the organic light emitting diode can still be operated. Therefore, in the embodiment shown in FIG. 8, in order to reduce current leakage, the length of the conductive structure is shortened to reduce the total current to prevent current leakage.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A middle voltage transistor structure, comprising:
a substrate;
a gate structure disposed on the substrate;
a source lightly doped region and a drain lightly doped region embedded within the substrate at two sides of the gate structure;
a conductive structure contacting the lightly drain doped region;
a first spacer surrounding the gate structure; and
a second spacer surrounding the conductive structure; wherein the first spacer contacts the second spacer.

2. The middle voltage transistor structure of claim 1, wherein the gate structure comprises a middle voltage dielectric layer, a first polysilicon layer and a first silicide disposed on the substrate from bottom to top, the conductive structure comprises a second polysilicon layer and a second silicide disposed on the substrate from bottom to top, and the second polysilicon layer contacts the drain lightly doped region.

3. The middle voltage transistor structure of claim 1, wherein the gate structure comprises a middle voltage dielectric layer, a first polysilicon layer and a first silicide disposed on the substrate from bottom to top, the conductive structure comprises a low voltage dielectric layer, a second polysilicon layer and a second silicide disposed on the substrate from bottom to top, and the low voltage dielectric layer contacts the drain lightly doped region.

4. The middle voltage transistor structure of claim 3, wherein a thickness of the middle voltage dielectric layer is greater than a thickness of the low voltage dielectric layer.

5. The middle voltage transistor structure of claim 1, wherein a top surface of the gate structure is aligned with a top surface of the conductive structure.

6. The middle voltage transistor structure of claim 1, further comprising a source doped region disposed in the source lightly doped region, wherein no drain doped region is disposed in the drain lightly doped region.

7. The middle voltage transistor structure of claim 1, wherein the second spacer contacts the drain lightly doped region.

8. A layout of a middle voltage transistor structure, comprising:
a substrate, wherein the substrate comprises an active region, a shallow trench isolation surrounds the active region, and the active region comprises four corners;
a gate structure disposed on the substrate, the gate structure extending along a first direction, and the gate structure intersecting the active region and covering the shallow trench isolation; and
a conductive structure disposed on a side of the gate structure, and the conductive structure extending along the first direction; wherein the conductive structure covers the shallow trench isolation and covers one of the four corners.

9. The layout of a middle voltage transistor structure of claim 8, further comprising a first spacer surrounding the gate structure and a second spacer surrounding the conductive structure, wherein the first spacer contacts the second spacer.

10. The layout of a middle voltage transistor structure of claim 8, further comprising a source lightly doped region and a drain lightly doped region embedded within the substrate at two sides of the gate structure, and the conductive structure contacts the drain lightly doped region.

11. The layout of a middle voltage transistor structure of claim 8, wherein along the first direction, a length of the conductive structure is smaller than a length of the gate structure.

12. The layout of a middle voltage transistor structure of claim 11, further comprising a dummy conductive structure contacting the drain lightly doped region and the shallow trench isolation, wherein the dummy conductive structure and the conductive structure are disposed on a same side of the gate structure and the dummy conductive structure is not connected to the conductive structure, and the dummy conductive structure covers another one of the four corners.

13. The layout of a middle voltage transistor structure of claim 12, wherein the dummy conductive structure and the conductive structure are stacked by same material layers in the same order.

14. The layout of a middle voltage transistor structure of claim 11, wherein the conductive structure only covers one of the four corners.

15. The layout of a middle voltage transistor structure of claim 8, wherein along the first direction, a length of the conductive structure is the same as a length of the gate structure, and the conductive structure covers two of the four corners.

16. A fabricating method of a middle voltage transistor structure, comprising:
providing a substrate;
forming a source lightly doped region and a drain lightly doped region embedded in the substrate;
forming a middle voltage dielectric layer disposed between the source lightly doped region and the drain lightly doped region;
simultaneously forming a first polysilicon layer and a second polysilicon layer, wherein the first polysilicon layer overlaps the middle voltage dielectric layer, and the second polysilicon layer covers part of the drain lightly doped region; and
forming a first spacer and a second spacer, wherein the first spacer surrounds the first polysilicon layer and the middle voltage dielectric layer, the second spacer surrounds the second polysilicon layer, and the first spacer contacts the second spacer.

17. The fabricating method of a middle voltage transistor structure of claim 16, further comprising:
performing an ion implantation process to form a source doped region within the source lightly doped region by taking the first polysilicon layer, the second polysilicon layer, the first spacer and the second spacer as a mask; and
performing a silicide process to transform part of the first polysilicon layer into a first silicide, part of the second polysilicon layer into a second silicide and part of the source doped region into a third silicide.

18. The fabricating method of a middle voltage transistor structure of claim 16, further comprising after forming the middle voltage dielectric layer and before forming the second polysilicon layer, forming a low voltage dielectric layer covering the drain lightly doped region, wherein the low voltage dielectric layer overlaps the second polysilicon layer.

19. The fabricating method of a middle voltage transistor structure of claim 18, further comprising forming current between the source lightly doped region and the second polysilicon layer at 8 to 10 volts to break down the low voltage dielectric layer.

20. The fabricating method of a middle voltage transistor structure of claim 18, wherein a thickness of the middle voltage dielectric layer is greater than a thickness of the low voltage dielectric layer.
